(19) United States
(12) Patent Application Publication
(10) Pub. No.: US 2025/0149379 A1
(43) Pub. Date: May 8, 2025

(54) SEMICONDUCTOR DEVICE WITH SHALLOW TRENCH ISOLATION PROTECTION LAYER

(71) Applicant: TAIWAN SEMICONDUCTOR MANUFACTURING COMPANY, LTD., Hsinchu (TW)

(72) Inventors: Ching-Hung CHEN, Miaoli County (TW); Yen-Chun HUANG, New Taipei City (TW); Yu-Wei CHOU, Hsinchu City (TW); Zhen-Cheng WU, Hsinchu County (TW)

(73) Assignee: TAIWAN SEMICONDUCTOR MANUFACTURING COMPANY, LTD., Hsinchu (TW)

(21) Appl. No.: 18/500,201

(22) Filed: Nov. 2, 2023

(51) Int. Cl. H01L 21/764; H01L 29/06; H01L 29/423; H01L 29/66; H01L 29/775

(52) U.S. Cl. CPC H01L 21/764; H10D 30/014; H10D 30/43; H10D 30/6735; H10D 62/121; H10D 64/017

(57) ABSTRACT

A method includes following steps. A semiconductor fin is formed on a substrate. A shallow trench isolation (STI) region is formed around a lower portion of the semiconductor fin. An STI protection layer is over the STI region. After forming the STI protection layer, source/drain recesses are etched in the semiconductor fin. Source/drain epitaxial regions are formed in the source/drain recesses.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 5, 6A, 17A, 18A, and 19A illustrate reference cross-section A-A′ illustrated in FIG. 1 that extends through a gate region along a longitudinal axis of the gate region.

FIGS. 6B, 7B, 8B, 9B, 10B, 11B, 12B, 13B, 14B, 15B, 16B, 17B, 18B, 19B, and 20B illustrate reference cross-section B-B′ illustrated in FIG. 1 that extends through a fin along a longitudinal axis of the fin.

FIGS. 7A, 8A, 9A, 10A, 11A, 12A, 13A, 14A, 15A, 16A, and 20A illustrate reference cross-section C-C′ illustrated in FIG. 1 that extends through source/drain regions along the longitudinal direction of the gate region.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a nanosheet transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents.

In fabricating GAA devices, shallow trench isolation (STI) dielectric is vulnerable to damage during subsequent processing steps, such as etching source/drain recesses within a multi-layer epitaxial stack. Such damage to the STI dielectric adversely affects the manufacturing yield of integrated circuits. To address this issue, the present disclosure provides, in various embodiments, an additional STI protection layer formed over the STI dielectric before etching source/drain recesses in the multi-layer epitaxial stack. The protection layer serves as a protective barrier against the chemical etchants employed during the source/drain recess etching process, effectively mitigating damage to the underlying STI dielectric. Moreover, the STI protection layer is engineered using non-conformal deposition methods, for example, plasma enhanced chemical vapor deposition (PECVD). This technique results in the formation of unfilled voids within the STI protection layer, thereby reducing its dielectric constant and improving the overall resistance-capacitance (RC) delay performance of the integrated circuits.

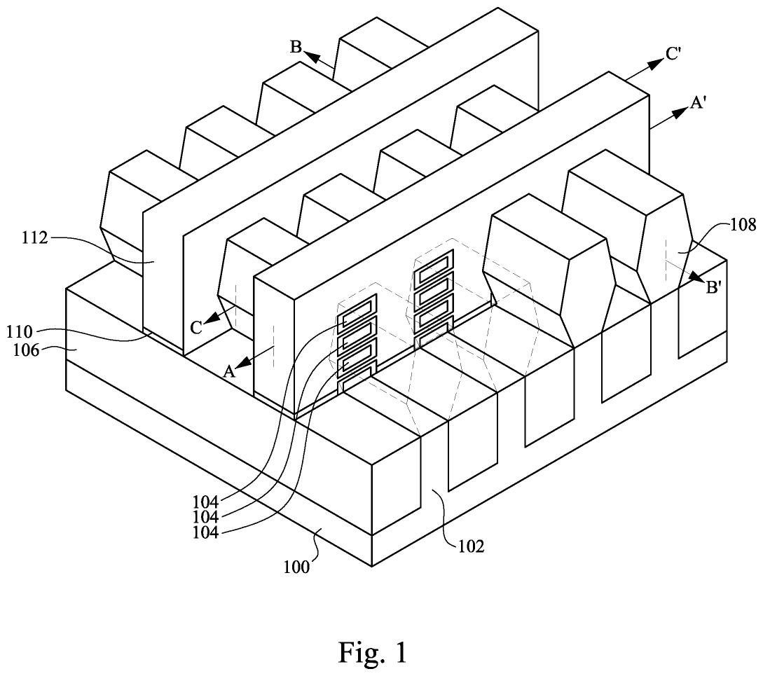

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. The isolation regions 106 are formed in trenches between the fins 102 and thus can be interchangeably referred to as shallow trench isolation (STI) regions. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

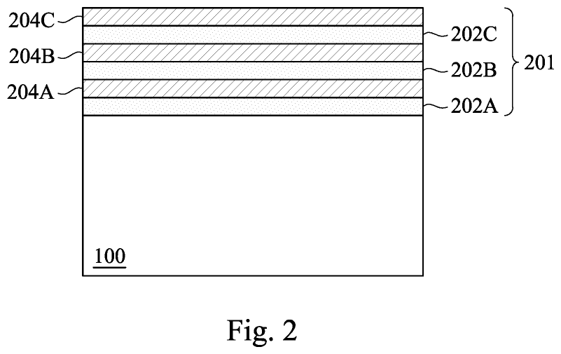

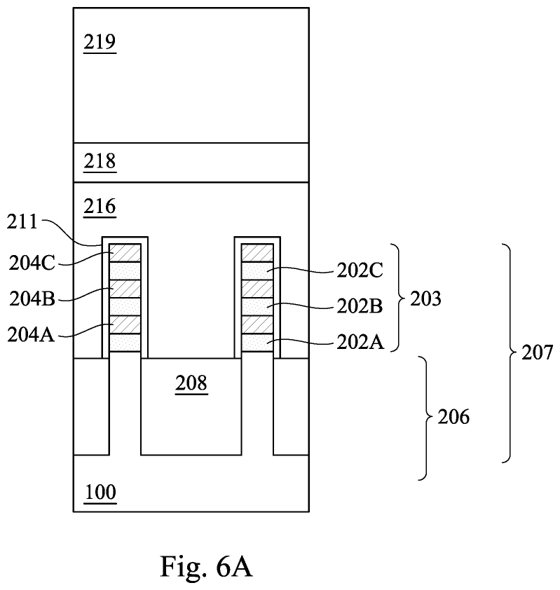

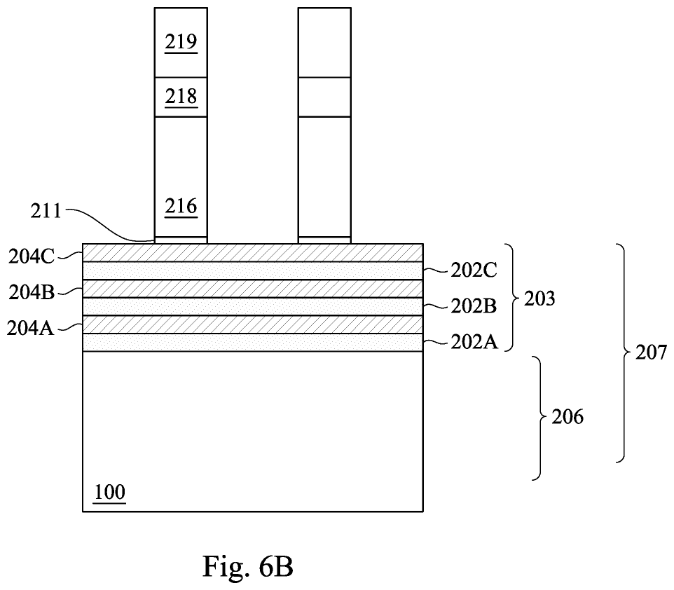

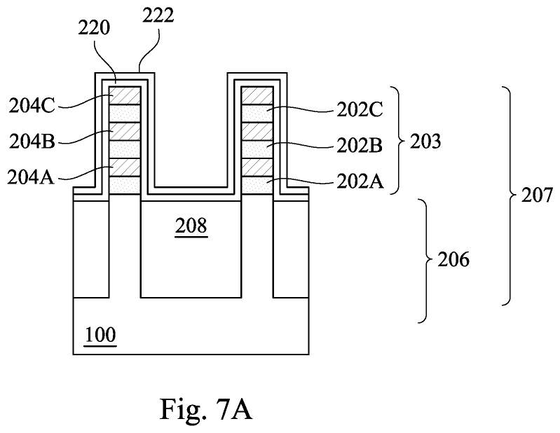

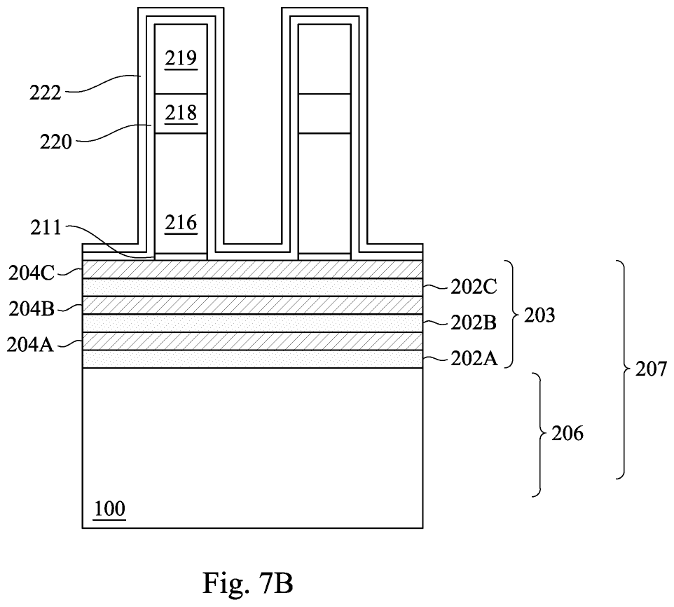

FIGS. 2 through 20B are cross-sectional views and top views of intermediate stages in the manufacturing of GAA-FETs, in accordance with some embodiments. FIGS. 2 through 5, 6A, 17A, 18A, and 19A illustrate reference cross-section A-A′ illustrated in FIG. 1 that extends through a gate region along a longitudinal axis of the gate region. FIGS. 6B, 7B, 8B, 9B, 10B, 11B, 12B, 13B, 14B, 15B, 16B, 17B, 18B, 19B, and 20B illustrate reference cross-section B-B′ illustrated in FIG. 1 that extends through a fin along a longitudinal axis of the fin. FIGS. 7A, 8A, 9A, 10A, 11A, 12A, 13A, 14A, 15A, 16A, and 20A illustrate reference cross-section C-C′ illustrated in FIG. 1 that extends through source/drain regions along the longitudinal direction of the gate region.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

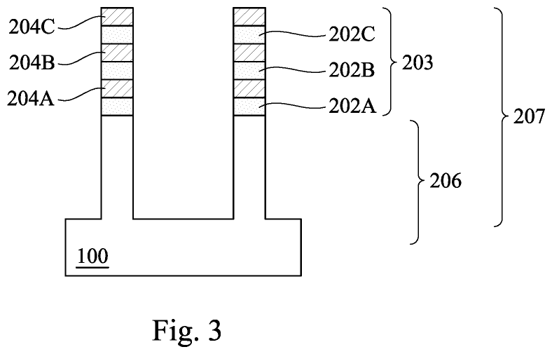

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and corresponding nanostructures 203 directly above the fin structure 206 can be collectively referred to as a semiconductor fin 207 extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

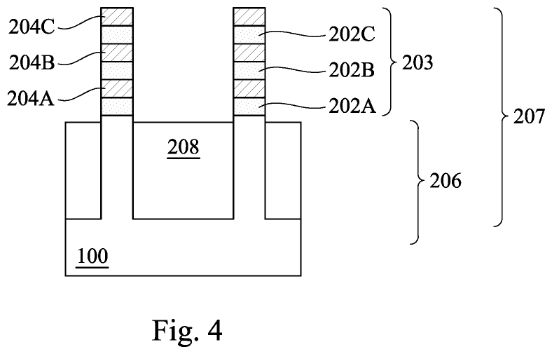

In FIG. 4, shallow trench isolation (STI) regions 208 are formed adjacent the fin structures 206. The STI regions 208 may be formed by depositing an insulation material over the substrate 100 and the semiconductor fins 207, and between adjacent semiconductor fins 207. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100 and the semiconductor fins 207. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etching the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

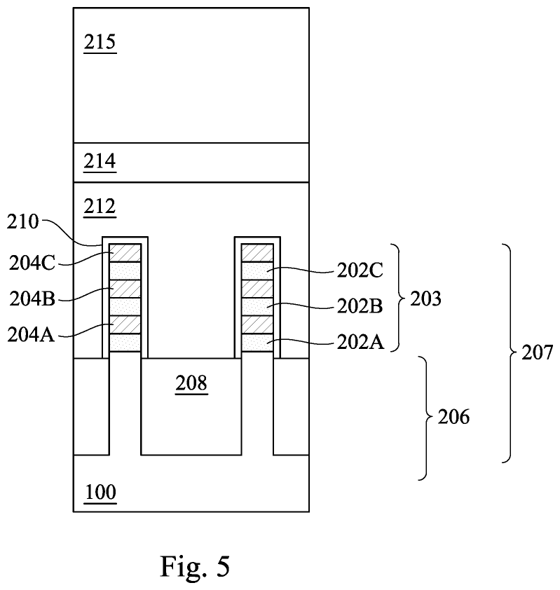

In FIG. 5, a dummy dielectric layer 210 is formed on the semiconductor fins 207. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a hard mask layer is formed over the dummy gate layer 212. The dummy gate layer 212 may be deposited over the dummy dielectric layer 210 and then planarized, such as by a CMP. The mask layer may be a dual-layer film including a bottom mask layer 214 deposited over the dummy gate layer 212 and a top mask layer 215 deposited over the bottom mask layer 214. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The bottom mask layer 214 and the top mask layer 215 include SiO₂, SiCN, SiON, Al₂O₃, SiN, or other suitable materials. In some embodiments, the bottom mask layer 214 and the top mask layer 215 include different materials. For example, the bottom mask layer 212 includes silicon nitride, and the top mask layer 215 includes silicon oxide.

It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

In FIGS. 6A and 6B, the bottom and top mask layers 214 and 215 (see FIG. 5) may be patterned using acceptable photolithography and etching techniques to form bottom and top masks 218 and 219. The pattern of the masks 218 and 219 then may be transferred to the dummy gate layer 212 and to the dummy dielectric layer 210 to form dummy gates 216 and dummy gate dielectrics 211, respectively. The dummy gates 216 cover respective channel regions of semiconductor fins 207. The pattern of the masks 218, 219 may be used to physically separate each of the dummy gates 216 from adjacent dummy gates 216. The dummy gates 216 may also have a lengthwise direction substantially perpendicular to the lengthwise direction of respective fin structures 206.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218, 219; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, silicon carbon nitride, silicon carbon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like. In some embodiments, the first and second spacer layers 220 and 222 are both nitride-based materials but different in carbon concentration. For example, the first spacer layer 220 has a higher carbon atomic concentration than the second spacer layer 222. For example, the first spacer layer 220 may be silicon carbon nitride or silicon carbon oxynitride, and the second spacer layer 222 may be silicon nitride or silicon oxynitride. In some embodiments, a total thickness of the first and second spacer layers 220 and 222 is in a range from about 8 nm to about 12 nm, e.g., about 10 nm.

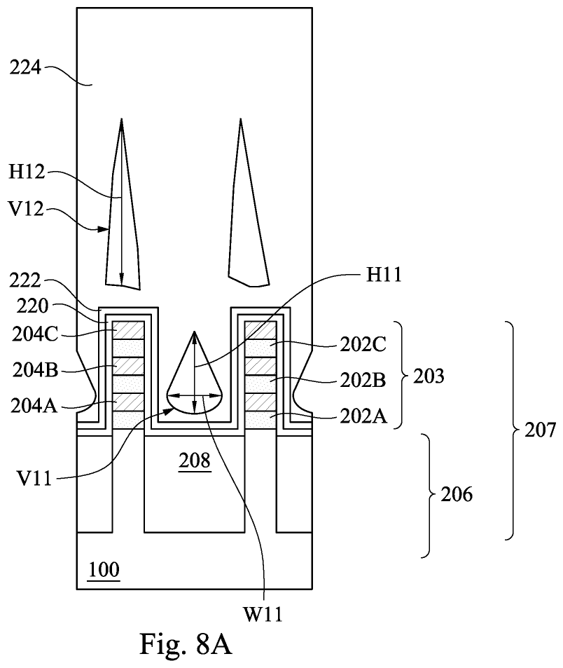

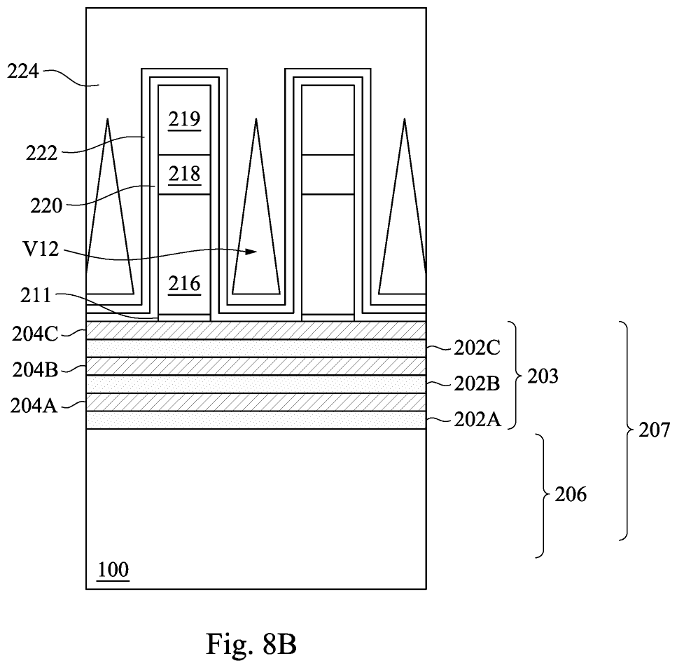

In FIGS. 8A and 8B, an STI protection layer 224 is formed over the second spacer layer 222. In some embodiments, the STI protection layer 224 is deposited over the second spacer layer 222 by using a non-conformal deposition method, e.g., a plasma enhanced chemical vapor deposition (PECVD) process. Because the STI protection layer 224 is deposited into a narrow trench between adjacent nanostructures 203 as illustrated in FIG. 8A, the non-conformal deposition allows for forming unfilled voids V11 within the STI protection layer 224 in between the nanostructures 203. Moreover, because the STI protection layer 224 is also deposited into a narrow trench between adjacent dummy gates 216 as illustrated in FIG. 8B, the non-conformal deposition method also allows for forming unfilled voids V12 within the STI protection layer 224 in between the dummy gates 216.

In particular, when PECVD is applied to deposit the STI protection layer 224 in narrow trenches, such as the trench between the nanostructures 203 and/or the trench between the dummy gates 216, the rate of deposition on the top corners of trenches may differ from (e.g., faster than) that at the bottoms of the trenches. This discrepancy in deposition rates creates conditions ripe for the formation of unfilled voids within the deposited material. Unfilled voids V11 appear predominantly in the trench between adjacent nanostructures 203, which are characterized by a high aspect ratio (i.e., ratio of trench depth to trench width) that amplifies the deposition rate discrepancies, and unfilled voids V12 appear predominantly in the trench between adjacent dummy gates 216, which are characterized by a high aspect ratio (i.e., ratio of trench depth to trench width) that amplifies the deposition rate discrepancies. In some embodiments, the aspect ratio of the trench between adjacent nanostructures 203 is greater than 2, 3, 4, 5, 6, 7, or 8. In some embodiments, the aspect ratio of the trench between adjacent dummy gates 216 is greater than 2, 3, 4, 5, 6, 7, 8, 9, or 10.

In some embodiments, the unfilled void V11 between the nanostructures 203 has a greatest void width W11 in a range between about 13 nm to about 20 nm, and a void height H11 less than about 30 nm. For example, the greatest void height H11 may be in a range between about 12 nm to about 25 nm. In some embodiments, the unfilled void V11 has a varying width that varies as a function of height. For example, the unfilled void V11 has a width increasing from a topmost position of the unfilled void V11 to a level at which the greatest void width W11 is located, then decreasing from the level at which the greatest void width W11 is located to a bottommost position of the unfilled void V11. In some embodiments, the void height H11 is greater than the void width W11. In particular, a ratio of the void height H11 to the void width W11 is greater than about 1:1, 2:1, 3:1, or 4:1, depending on aspect ratio of the trench between the nanostructures 203. In some embodiments, the unfilled void V11 extends upwards from above the STI region 208 and terminates at a position lower than a topmost position of a topmost channel layer 204C. Stated differently, the unfilled void has a bottommost position higher than the STI region 208 and a topmost position lower than a topmost position of a topmost channel layer 204C.

In some embodiments, the unfilled void V12 has a void height H12 greater than the void height H11 of the unfilled void V11, because the trench between dummy gates 216 has a deeper depth than the trench between the nanostructures 203. In some embodiments, a ratio of the void height H12 of the upper unfilled void V12 to the void height V11 of the lower unfilled void V11 is greater than about 1:1, 2:1, 3:1, 4:1, 5:1, or 6:1, depending on a ratio of the trench depth between dummy gates 216 to the trench depth between nanostructures 203.

In some embodiments, the STI protection layer 224 includes an oxide material (e.g., silicon oxide, SiO₂) or other suitable dielectric materials formed using a non-conformal deposition technique, such as PECVD, to create unfilled voids V11 and V12 within the deposited oxide materials in the narrow trench between nanostructures 203 and the narrow trench between dummy gates 216. In some embodiments where the STI protection layer 224 is silicon oxide, the STI protection layer 224 is deposited in a PECVD reaction chamber introduced with a gaseous mixture including a silicon-containing precursor, such as silane (SiH₄) or disilane (Si₂H₆), and an oxidizing agent, such as molecule oxygen (O₂) or ozone (O₃). These precursor gases dissociate into reactive species due to the RF energy applied to the PECVD reaction chamber. Once the reactive species reach the surface of the second spacer layer 222, surface reactions occur, leading to deposition of silicon oxide film. In PECVD, these reactions are not equally probable throughout the narrow trench between nanostructures 203 and the narrow trench between dummy gates 216. In particular, top corners of these trenches are exposed to higher ion flux, leading to a faster deposition rate compared to bottoms of these trenches. This difference in deposition rates results in the formation of unfilled voids V11, V12 within the deposited silicon oxide layer 224, after the PECVD is completed. Because the unfilled voids V11 and V22 are void of the dielectric material (e.g., silicon oxide) of the STI protection layer 224 but filled with air with having an extremely low dielectric constant (about 1) compared with the dielectric material (e.g., silicon oxide) of the STI protection layer 224, the parasitic capacitance in the resulting integrated circuits can be reduced, thus improving the resistance-capacitance (RC) delay performance.

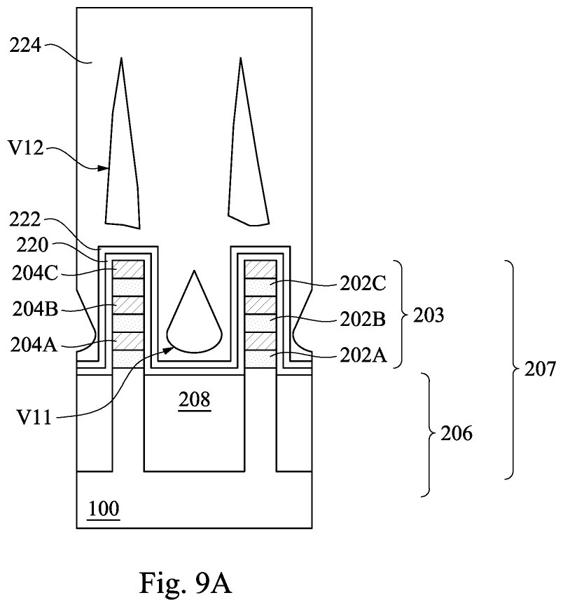

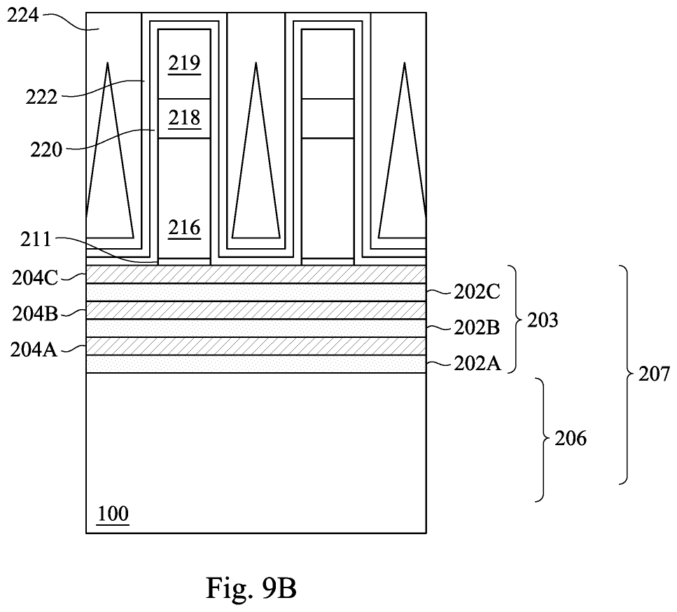

In FIGS. 9A-9B, a planarization process, such as a CMP process, is performed on the STI protection layer 224 until portions of the second spacer layer 222 over tops of the dummy gates 216 are exposed. In some embodiments, the CMP process may be a selective CMP process using slurry chemicals that polish the oxide material of the STI protection layer 224 at a faster removal rate than polishing the nitride-based material of the second spacer layer 222. In this way, the second spacer layer 222 can act as a detectable CMP end point. In some other embodiments, the CMP process is a timed CMP process with a predetermined CMP duration time.

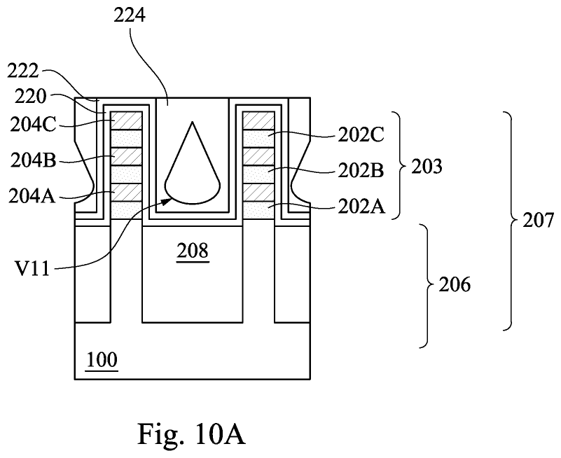

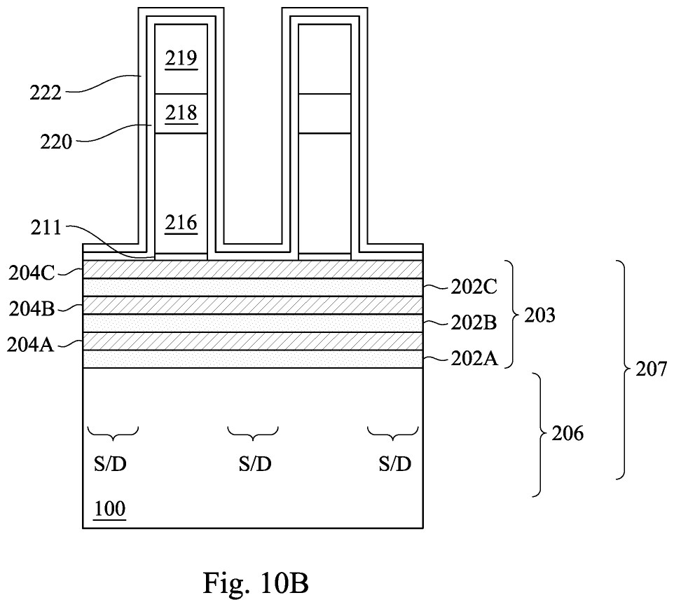

In FIGS. 10A-10B, the STI protection layer 224 is etched back until portions of the second spacer layer 222 over tops of the nanostructures 203 are exposed. The etch back process thus removes the STI protection layer 224 from above source/drain regions S/D of the nanostructures 203. In some embodiments, the STI protection layer 224 is etched back by a selective etching process using etchant chemicals that etches the oxide material of the STI protection layer 224 at a faster etch rate than etching the nitride-based material of the second spacer layer 222. In this way, the second spacer layer 222 can act as a detectable etching end point. In some other embodiments, the etch back process is a timed etching process with a predetermined etching duration time.

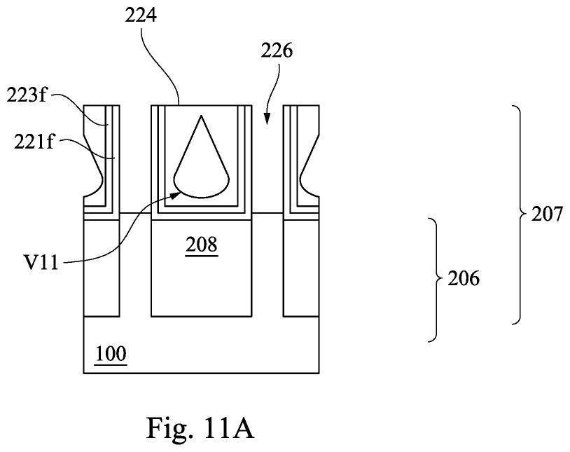

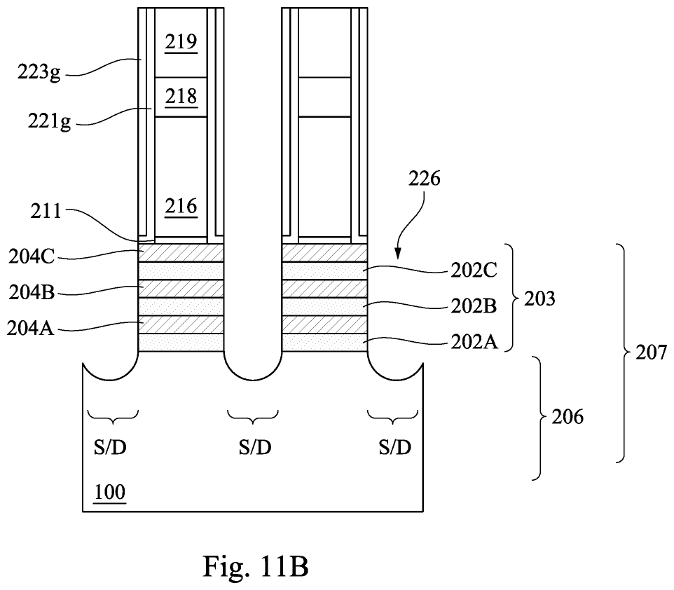

In FIGS. 11A and 11B, source/drain recesses 226 are formed in the semiconductor fins 207, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 11A, bottom surfaces of the source/drain recesses 226 may be approximately level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The anisotropic etching may be performed by a selective dry chemical etch with a plasma source and a reaction gas, serving for selectively etching first semiconductor layers 202 (e.g., SiGe) and second semiconductor layers 204 (e.g. Si) at an etch rate faster than etching the STI protection layer 224. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

During etching source/drain recesses 226 in the nanostructures 203, the etchant chemistry may unintentionally etch the surrounding STI regions 208, if they are not protected by the STI protection layer 224. Such unintended etching of STI regions 208 has the potential to negatively impact the manufacturing yield of integrated circuits. However, because the STI regions 208 are pre-coated with the STI protection layer 224 prior to initiating the etching process for the source/drain recesses 226, the STI protection layer 224 acts as an effective barrier against the chemical etchants, thereby reducing damage to the underlying STI regions 208. For example, the unintended STI height loss in the STI regions 208 caused by this source/drain etching step can be reduced to less than 3 nm.

Moreover, the etching process of forming source/drain recesses 226 also etches the first spacer layer 220 and the second spacer layer 222 to form inner gate spacers 221g and out gate spacers 223g on opposite sidewalls of the dummy gates 216, and to form inner fin spacers 221f and outer fin spacers 223f above opposite sidewalls of the fin structures 206. As will be discussed in greater detail below, these spacers act to self-align subsequently formed source/drain epitaxial material to source/drain regions S/D. Moreover, the inner fin spacers 221f and outer fin spacers 223f can serve to regulate the geometry of the source/drain epitaxial material. During etching source/drain recesses 226 in the nanostructures 203, the etchant chemistry may inadvertently cause erosion of surrounding spacer materials of inner and outer fin spacers 221f and 223f, leading to an unintentional height reduction in the inner and outer fin spacers 221f and 223f. Such unintended height reduction may adversely affect formation of source/drain epitaxial material, deviating from the target profile of source/drain epitaxial regions. However, by pre-coating the inner and outer fin spacers 221f and 223f with the STI protection layer 224 prior to initiating the etching process for the source/drain recesses 226, the STI protection layer 224 can act as an effective barrier against the chemical etchants, thereby mitigating the unintended height reduction in the fin spacers 221f and 223f. In some embodiments, after the etching process of forming source/drain recesses 226 is completed, top ends of the fin spacers 221f, 223f are substantially level with a top surface of the STI protection layer 224, and thus are higher than the topmost position of the unfilled void V11 with in the STI protection layer 224.

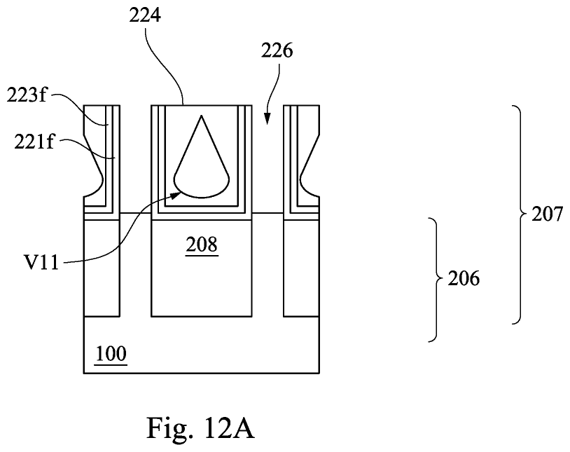

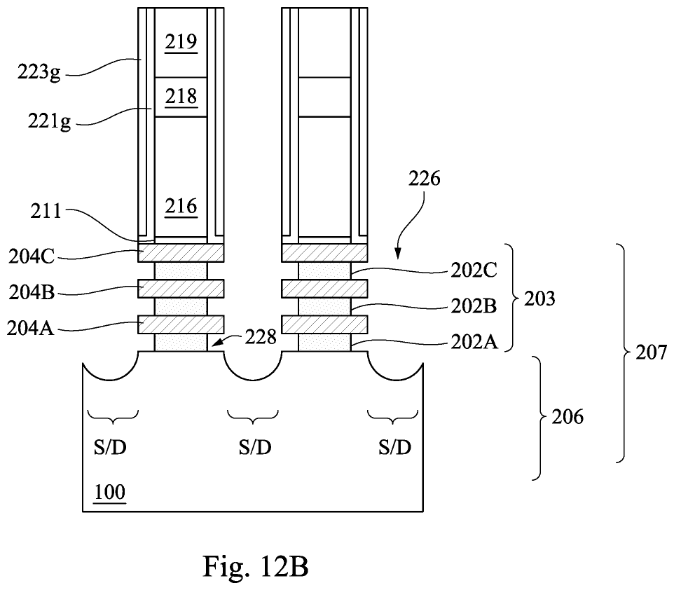

In FIGS. 12A and 12B, portions of sidewalls of the layers of the multi-layer stack 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 12B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

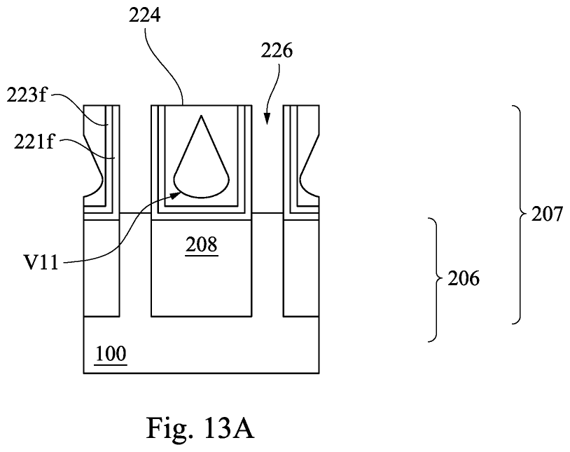

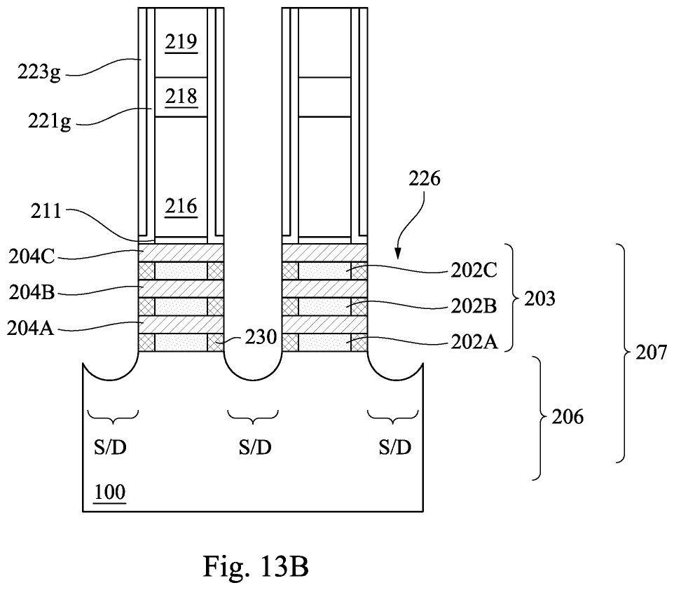

In FIGS. 13A-13B, inner spacers 230 are formed in the sidewall recess 228. The inner spacers 230 may be formed by depositing an inner spacer layer (not separately illustrated) over the structures illustrated in FIGS. 12A and 12B. The inner spacers 230 act as isolation features between subsequently formed source/drain regions and gate structure. As will be discussed in greater detail below, source/drain epitaxial regions will be formed in the recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

Moreover, although the outer sidewalls of the inner spacers 230 are illustrated as being straight in FIG. 13B, the outer sidewalls of the inner spacers 230 may be concave or convex. The inner spacer layer may be etched by an anisotropic etching process, such as RIE, NBE, or the like. The inner spacers 230 may be used to prevent damage to subsequently formed source/drain epitaxial regions by subsequent etching processes, such as etching processes used to form gate structures.

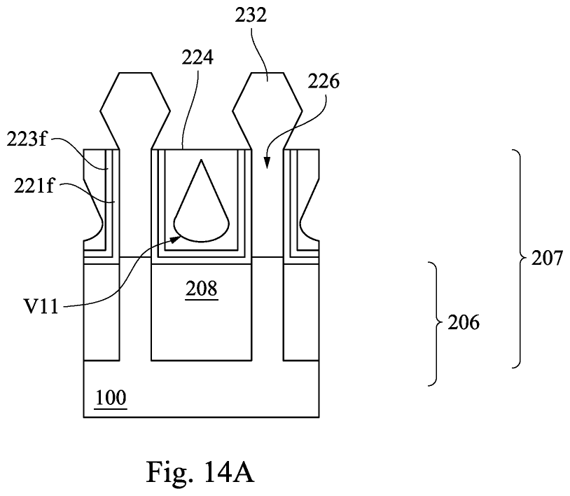

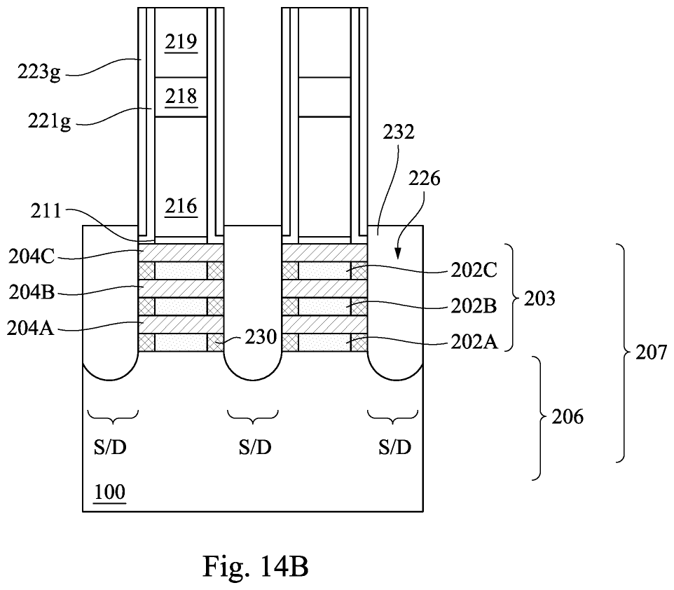

In FIGS. 14A-14B, source/drain epitaxial regions 232 are formed in the source/drain recesses 226. In some embodiments, the source/drain regions 232 may exert stress on the second nanostructures 204, thereby improving device performance. As illustrated in FIG. 14B, the epitaxial source/drain regions 232 are formed in the source/drain recesses 226 such that each dummy gate 216 is disposed between respective neighboring pairs of the source/drain epitaxial regions 232. In some embodiments, the gate spacers 221g, 223g collectively serve to separate the epitaxial source/drain regions 232 from the dummy gates 212, and the inner spacers 230 serve to separate the epitaxial source/drain regions 232 from the first nanostructures 202 by an appropriate lateral distance so that the source/drain epitaxial regions 232 do not short out with subsequently formed gates of the resulting GAA-FETs.

In some embodiments, the source/drain epitaxial regions 232 may include any acceptable material appropriate for n-type GAA-FETs. For example, if the second nanostructures 204 are silicon, the source/drain epitaxial regions 232 may include materials exerting a tensile strain on the second nanostructures 204, such as silicon carbide, phosphorous doped silicon carbide, silicon phosphide, or the like. In some embodiments, the source/drain epitaxial regions 232 may include any acceptable material appropriate for p-type GAA-FETs. For example, if the second nanostructures 204 are silicon, the source/drain epitaxial regions 232 may comprise materials exerting a compressive strain on the second nanostructures 204, such as silicon germanium, boron doped silicon germanium, germanium, germanium tin, or the like. The source/drain epitaxial regions 232 may have surfaces raised from respective upper surfaces of the nanostructures 203 and may have facets.

The source/drain epitaxial regions 232 may be implanted with dopants to serve as source/drain of transistors, followed by an anneal. The source/drain epitaxial regions 232 may have an impurity concentration of between about 1×10¹⁷ atoms/cm³ and about 1×10²² atoms/cm³. The n-type and/or p-type impurities for source/drain regions may be any of the impurities previously discussed. In some embodiments, the source/drain epitaxial regions 232 may be in situ doped during growth.

As a result of the epitaxy processes used to form the epitaxial source/drain regions 232, upper portions of the source/drain epitaxial regions 232 have facets which expand laterally outward beyond fin spacers 211f, 223f, but lower portions of the source/drain epitaxial regions 232 are confined within trench between the fin spacers 221f, 223f, as illustrated in FIG. 14A. In particular, adjacent source/drain epitaxial regions 232 remain separated (i.e., unmerged) after the epitaxy process is completed, because the fin spacers 221f, 223f without unintended height reduction can effectively confine the lateral epitaxial growth.

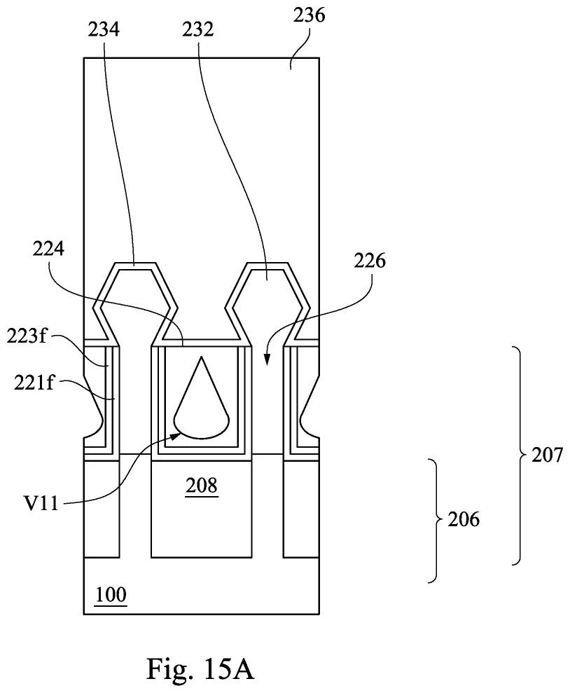

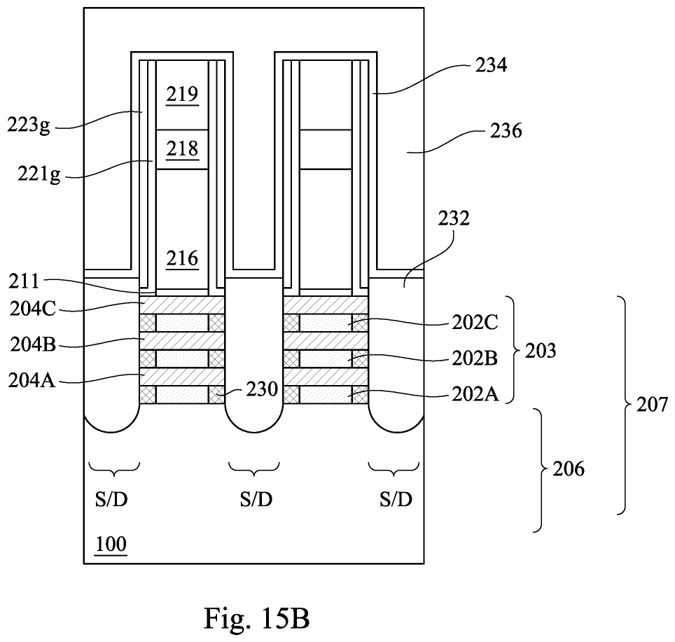

In FIGS. 15A-15B, an interlayer dielectric (ILD) layer 236 is deposited over the structure illustrated in FIGS. 14A-14B. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the source/drain epitaxial regions 232. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

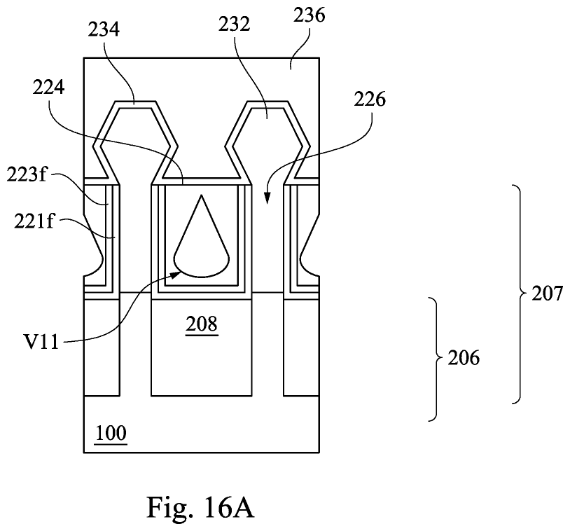

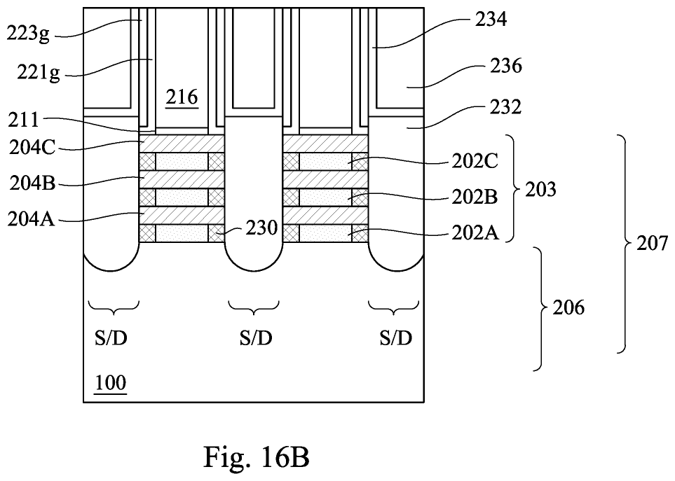

In FIGS. 16A-16B, a planarization process, such as a CMP, may be performed to level the top surface of the ILD layer 236 with the top surfaces of the dummy gates 216 or the masks 218. The planarization process may also remove the masks 218, 219 on the dummy gates 216, and portions of the gate spacers 221g, 223g along sidewalls of the masks 218, 219. After the planarization process, top surfaces of the dummy gates 216, the gate spacers 221g, 223g, and the ILD layer 236 are level within process variations. Accordingly, the top surfaces of the dummy gates 216 are exposed through the ILD layer 236. In some embodiments, the masks 218 may remain, in which case the planarization process levels the top surface of the ILD layer 236 with top surface of the masks 218 and the first spacers 221.

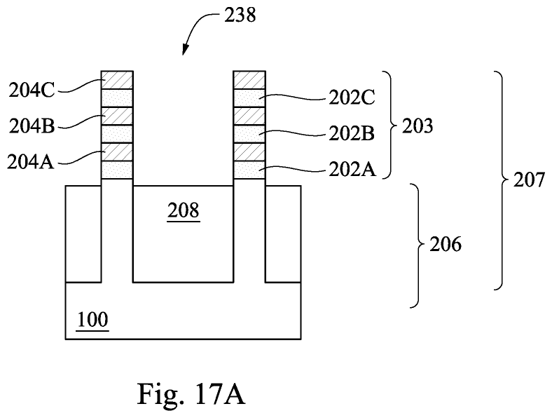

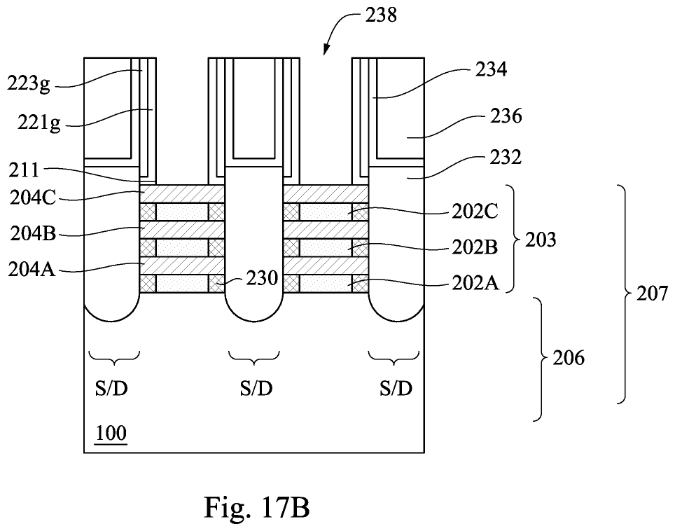

In FIGS. 17A and 17B, the dummy gates 216, and the masks 218 if present, are removed in one or more etching steps, so that gate trenches 238 are formed between corresponding inner gate spacers 221g. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the gate spacers 221g, 223g. Each gate trench 238 exposes and/or overlies portions of nanostructures 204, which will serve as channel regions in subsequently completed GAA-FETs. The nanostructures 204 serving as the channel regions are disposed between neighboring pairs of the source/drain epitaxial regions 232. During the removal, the dummy dielectric layers 211 may be used as etch stop layers when the dummy gates 216 are etched. The dummy dielectric layers 211 may then be removed after the removal of the dummy gates 216.

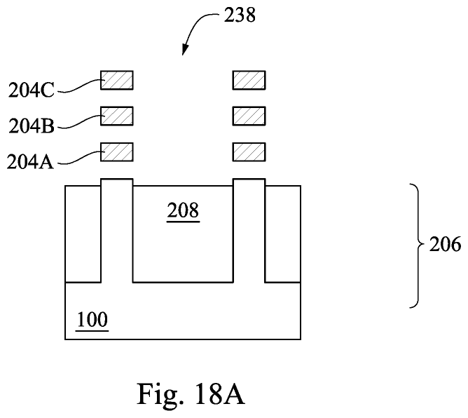

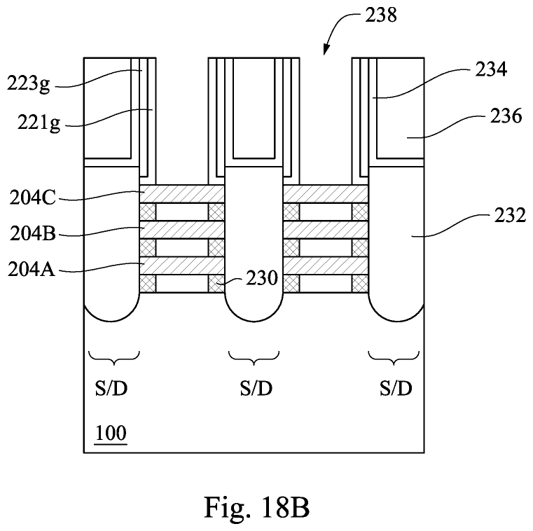

In FIGS. 18A and 18B, the first nanostructures 202 in the gate trenches 238 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 12A-12B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

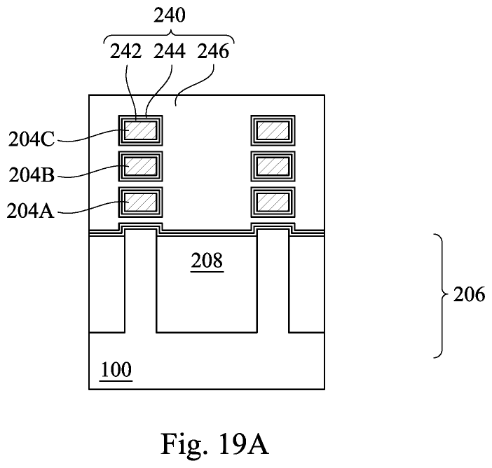

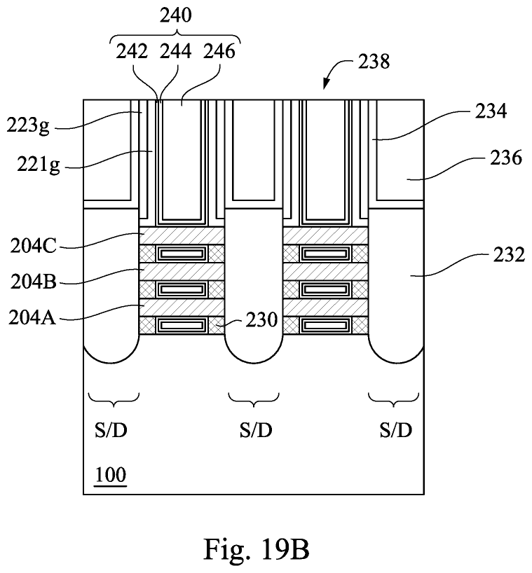

In FIGS. 19A and 19B, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, the high-k/metal gate structures 240 are formed within the sheet-to-sheet spaces provided by the release of nanosheets 204. In various embodiments, the high-k/metal gate structure 240 includes a gate dielectric layer 242 formed around the nanosheets 204, a work function metal layer 244 formed around the gate dielectric 242, and a fill metal 246 formed around the work function metal layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the ILD layer 236. As illustrated in the cross-sectional view of FIG. 19A, the high-k/metal gate structure 240 surrounds each of the nanosheets 204, and thus is referred to as a gate of a GAA FET.

In some embodiments, the gate dielectric layer 242 includes an interfacial layer, which may be silicon oxide formed on exposed surfaces of semiconductor materials in the gate trenches 238 by using, for example, thermal oxidation, chemical oxidation, wet oxidation or the like. In some embodiments, the gate dielectric layer 242 may further comprises a high-k gate dielectric layer deposited over the interfacial layer. High-k gate dielectrics, as used and described herein, include dielectric materials having a high dielectric constant, for example, greater than that of thermal silicon oxide (˜3.9). In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the work function metal layer 244 may include one or more work function metals stacked one over another. The one or more work function metals in the work function metal layer 244 provide a suitable work function for the high-k/metal gate structures 240. For an n-type GAA FET, the work function metal layer 244 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the work function metal layer 244 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

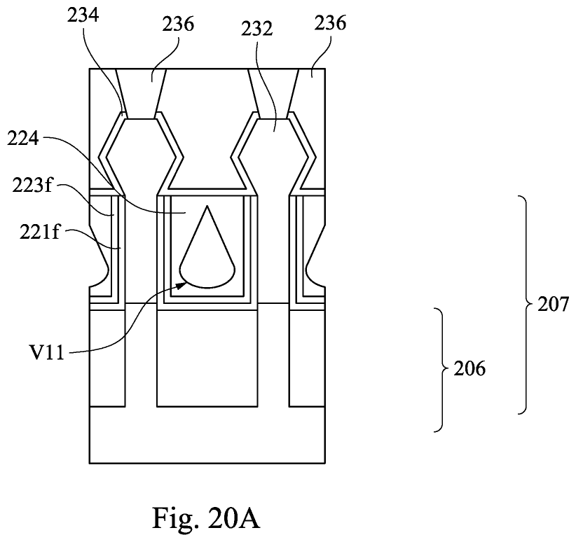

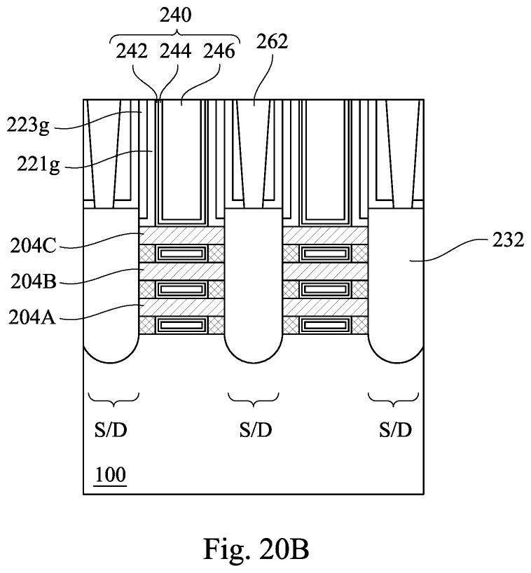

In FIGS. 20A-20B, source/drain contacts 262 are formed extending through the CESL 234 and the ILD layer 236. Formation of the source/drain contacts 262 includes, by way of example and not limitation, performing one or more etching processes to form contact openings extending though the ILD layer 236 and the CESL 234 to expose the source/drain epitaxial regions 232, depositing one or more metal materials (e.g., W, Ru, Co, Cu, Ti, TiN, Ta, TaN, Mo, Ni, the like or combinations thereof) overfilling the contact openings, and then performing a CMP process to remove excessive metal materials outside the contact openings. In some embodiments, metal silicide regions may be formed on the source/drain epitaxial regions 232 before forming the source/drain contacts 262.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the STI protection layer can serve as a protective barrier against the chemical etchants employed during the source/drain recess etching process, effectively mitigating damage to the underlying STI dielectric, which in turn improve manufacturing yield of integrated circuits. Another advantage is that the STI protection layer can further mitigate unintended height reduction in the spacer materials, which in turn aids in growing source/drain epitaxial regions with target profiles. Another advantage is that the STI protection layer is formed with unfilled voids, thereby reducing an overall dielectric constant of the STI protection layer and improving the resistance-capacitance (RC) delay performance of the integrated circuits.

In some embodiments, a method includes forming a semiconductor fin extending from a substrate, forming a shallow trench isolation (STI) region around a lower portion of the semiconductor fin, forming an STI protection layer over the STI region, after forming the STI protection layer, etching source/drain recesses in the semiconductor fin, and forming source/drain epitaxial regions in the source/drain recesses. In some embodiments, the STI protection layer is formed using a non-conformal deposition process. In some embodiments, the non-conformal deposition process is plasma enhanced chemical vapor deposition. In some embodiments, the STI protection layer has an unfilled void within the STI protection layer. In some embodiments, the unfilled void has a width varying as function of height. In some embodiments, the unfilled void has a topmost position lower than a topmost position of the semiconductor fin. In some embodiments, the unfilled void is above the semiconductor fin. In some embodiments, the method further includes forming gate structures over the semiconductor fin, and the unfilled void is in a position laterally between the gate structures. In some embodiments, the method further includes forming a spacer layer over the gate structures, and performing a chemical mechanical polish (CMP) process on the STI protection layer until first portions of the spacer layer over top surfaces of the gate structures is exposed. In some embodiments, the method further includes after performing the CMP process, etching back the STI protection layer until a second portion of the spacer layer over a top surface of the semiconductor fin is exposed. In some embodiments, etching the source/drain recesses in the semiconductor fin is performed after etching back the STI protection layer.

In some embodiments, a method includes forming a plurality of semiconductor fins over a substrate, forming an STI region between the plurality of semiconductor fins, depositing a protection layer over the STI region, and forming source/drain epitaxial regions over the plurality of semiconductor fins. The protection layer has a first unfilled void between the plurality of semiconductor fins after the deposition is completed. In some embodiments, the method further includes forming a plurality of gates over the plurality of semiconductor fins. The protection layer is further deposited over the plurality of gates, and the protection layer has a second unfilled void between the plurality of gates. In some embodiments, the second unfilled void has a height greater than a height of the first unfilled void. In some embodiments, the method further includes prior to forming the source/drain epitaxial regions, etching back the protection layer to fall below top surfaces of the gates. In some embodiments, the method further includes etching source/drain recesses in the plurality of semiconductor fins. Bottoms of the source/drain recesses are lower than a bottommost position of the first unfilled void, and the source/drain epitaxial regions are formed in the source/drain recesses.

In some embodiments, a device includes a fin structure extending from a substrate, an STI region around the first fin structure, a plurality of semiconductor nanostructures over the fin structure and arranged one above another in a spaced apart manner, a gate surrounding each of the plurality of semiconductor nanostructures, a first source/drain epitaxial region over the fin structure and interfacing first ends of the plurality of semiconductor nanostructures, and a protection layer over the STI region and having a top surface lower than a top surface of the first source/drain epitaxial region. In some embodiments, the device further includes a second source/drain epitaxial region interfacing second ends of the plurality of semiconductor nanostructures. In some embodiments, the protection layer has an unfilled void. In some embodiments, the unfilled void has a width changing as a function of height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor fin extending from a substrate;
forming a shallow trench isolation (STI) region around a lower portion of the semiconductor fin;
forming an STI protection layer over the STI region;
after forming the STI protection layer, etching source/drain recesses in the semiconductor fin; and
forming source/drain epitaxial regions in the source/drain recesses.

2. The method of claim 1, wherein the STI protection layer is formed using a non-conformal deposition process.

3. The method of claim 2, wherein the non-conformal deposition process is plasma enhanced chemical vapor deposition.

4. The method of claim 1, wherein the STI protection layer has an unfilled void within the STI protection layer.

5. The method of claim 4, wherein the unfilled void has a width varying as function of height.

6. The method of claim 4, wherein the unfilled void has a topmost position lower than a topmost position of the semiconductor fin.

7. The method of claim 4, wherein the unfilled void is above the semiconductor fin.

8. The method of claim 7, further comprising:
forming gate structures over the semiconductor fin, wherein the unfilled void is in a position laterally between the gate structures.

9. The method of claim 8, further comprising:
forming a spacer layer over the gate structures, wherein the STI protection layer is formed over the spacer layer; and
performing a chemical mechanical polish (CMP) process on the STI protection layer until first portions of the spacer layer over top surfaces of the gate structures is exposed.

10. The method of claim 9, further comprising:
after performing the CMP process, etching back the STI protection layer until a second portion of the spacer layer over a top surface of the semiconductor fin is exposed.

11. The method of claim 10, wherein etching the source/drain recesses in the semiconductor fin is performed after etching back the STI protection layer.

12. A method, comprising:
forming a plurality of semiconductor fins over a substrate;
forming an STI region between the plurality of semiconductor fins;
depositing a protection layer over the STI region, the protection layer having a first unfilled void between the plurality of semiconductor fins after the deposition is completed; and
forming source/drain epitaxial regions over the plurality of semiconductor fins.

13. The method of claim 12, further comprising:
forming a plurality of gates over the plurality of semiconductor fins, wherein the protection layer is further deposited over the plurality of gates, and the protection layer has a second unfilled void between the plurality of gates.

14. The method of claim 13, wherein the second unfilled void has a height greater than a height of the first unfilled void.

15. The method of claim 13, further comprising:
prior to forming the source/drain epitaxial regions, etching back the protection layer to fall below top surfaces of the gates.

16. The method of claim 12, further comprising:
etching source/drain recesses in the plurality of semiconductor fins, wherein bottoms of the source/drain recesses are lower than a bottommost position of the first unfilled void, and the source/drain epitaxial regions are formed in the source/drain recesses.

17. A device, comprising:
a fin structure extending from a substrate;
an STI region around the fin structure;
a plurality of semiconductor nanostructures over the fin structure, the plurality of semiconductor nanostructures arranged one above another in a spaced apart manner;
a gate structure surrounding each of the plurality of semiconductor nanostructures;
a first source/drain epitaxial region over the fin structure and interfacing first ends of the plurality of semiconductor nanostructures; and
a protection layer over the STI region, the protection layer having a top surface lower than a top surface of the first source/drain epitaxial region.

18. The device of claim 17, further comprising:
a second source/drain epitaxial region interfacing second ends of the plurality of semiconductor nanostructures.

19. The device of claim 17, wherein the protection layer has an unfilled void.

20. The device of claim 19, wherein the unfilled void has a width changing as a function of height.
